(19) United States
(12) Patent Application Publication
(10) Pub. No.: US 2009/0217873 A1
(43) Pub. Date: Sep. 3, 2009

(54) ATOMIC LAYER DEPOSITION APPARATUS

(75) Inventors: Tomohisa Iino, Kanagawa (JP); Naomi Fukumaki, Kanagawa (JP); Yoshitake Kato, Kanagawa (JP)

Correspondence Address: YOUNG & THOMPSON, 209 Madison Street, Suite 500, ALEXANDRIA, VA, 22314, US

(73) Assignee: NEC ELECTRONICS CORPORATION, KANAGAWA (JP)

(21) Appl. No.: 12/370,648

(22) Filed: Feb. 13, 2009

(30) Foreign Application Priority Data
Feb. 28, 2008 (JP) 2008-048061

(51) Int. Cl. C23C 16/54

(52) U.S. Cl. 118/722

(57) ABSTRACT

An atomic layer deposition apparatus includes: a metal source gas supply tube, disposed in a side of a wafer to extend over the entire surface of the wafer, and capable of being supplied with a source gas from a first end to a second end; and an active gas supply tube, disposed in a side of a wafer to extend over the entire surface of the wafer, and capable of being supplied with a source gas from a first end to a second end, wherein the active gas supply tube is provided with a plurality of gas blow openings for blowing the active gas that is active over the wafer, and wherein the gas blow openings are disposed with gradually reduced inter-opening distances as being further from the first end to the second end of the active gas supply tube.

This application is based on Japanese patent application No. 2008-048,061, the content of which is incorporated hereinto by reference.

### BACKGROUND

1. Technical Field

The present invention relates to an atomic layer deposition apparatus.

2. Related Art

Under the circumstance of enhanced miniaturizations and increased integrations of DRAM in recent years, one of the critical problems is to ensure larger cell capacitance. A technique for ensuring larger cell capacitance is an approach for adopting a high dielectric constant film (high-k film) for a capacitive film. Typical high dielectric constant films contain, for example, tantalum pentoxide (Ta₂O₅), hafnium dioxide (HfO₂), zirconium dioxide (ZrO₂) and the like. Typical processes for depositing such types of films include a sputter process, a metal organic chemical vapor deposition (MO-CVD) process, an atomic layer deposition (ALD) process and the like. The atomic layer deposition process is a process that involves proceeding depositions by every single atomic layer, and the process is advantageous as the deposition process can he carried out at a low temperature and in addition an enhanced quality of film can be easily obtained.

Japanese Patent Laid-Open No. 2004-288,900 discloses an ALD apparatus having two nozzles disposed to face across a substrate to be processed. These nozzles include hollow pipe members having a plurality of openings formed along the elongating direction, and are configured to discharge a process gas from the openings. In the apparatus disclosed in Japanese Patent Laid-Open No. 2004-288,900, the openings provided in the hollow pipe member are evenly distributed.

Japanese Patent Laid-Open No. 2002-151,489 discloses a substrate processing unit having a processing chamber, which is provided with a first and a second process gas-supply ports so as to face across a substrate to be processed, and is also provided with a first and a second slit-like exhaust ports in directions substantially perpendicular to flows of the first and the second process gases around the first and the second process gas-supply ports so as to face across a substrate to be processed. The following procedures are described in Japanese Patent Laid-Open No. 2002-151,489. The first process gas is flowed from the first process gas supply port toward the first exhaust port along the surface of the substrate to be processed so that the first gas is adsorbed in the surface of the substrate to be processed. Then, the second process gas is flowed from the second process gas supply port toward the second exhaust port along the surface of the substrate to be processed so that the second gas is reacted with molecule of the adsorbed first gas to form one molecular layered high dielectric film

Japanese Patent Laid-Open No. 2002-151,489 discloses a configuration, in which decreased inter-opening distances of the nozzles for the gas supply ports are provided in the central section and increased inter-opening distances are provided in both ends thereof.

However, it was found according to the investigations of the present inventors that the cell capacitances of the formed capacitors are varied and thus locations of deteriorated cell capacitances are created in the wafer surface, when a process gas is supplied over a wafer serving as a substrate to be processed from the evenly arranged nozzles to form a capacitive film of a capacitor as described in Japanese Patent Laid-Open No. 2004-288,900.

In the atomic layer deposition process, a metal source gas is first supplied to deposit a metallic source material on the substrate, and then the deposited layer of the metal source material is activated with an active gas such as ozone and the like to create a capacitive films or the like. FIG. 13 is a diagram, which schematically illustrates a distribution of a cell capacitance in the surface of a capacitor having capacitive films formed by blowing a metal source gas and ozone from evenly distributed nozzles (gas blow openings), respectively, as will be discussed later. As shown in the diagram, the cell capacitance is reduced as being further from the gas supply opening toward the downstream. It is considered that this is because the gas supply rate is lower and more insufficient as being further in the downstream from the gas supply opening, leading to an insufficient quality of the formed capacitive film. Further, when the nozzles are closely arranged in the central section as described in Japanese Patent Laid-Open No. 2002-151,489, the gas supply rate is also more insufficient as being further in the downstream from the gas supply opening.

Japanese Patent Laid-Open No. H10-147,874 (1998) discloses that a flow rate of a reactive gas may be equalized by arranging the gas-supply ports having the feeding tubes for the deposition gas of the same diameter at inter-tube distances that are gradually decreased as being further from the gas supply tube. Japanese Patent Laid-Open No. H6-349,761 (1994) discloses nozzle tubes provided with larger number of gas supply pores, which are distributed at gradually decreased inter-pore distances as being further from the side of a gas inlet port toward the another end.

It is also described in the Japanese Patent Laid-Open No. H6-349,761 that such configuration provides uniform processing over the wafer.

A metal source gas and an active gas are employed in an atomic layer deposition process, as described above. The present inventors have found that a deterioration of the cell capacitance in the process with the atomic layer deposition apparatus as shown in FIG. 13 is due to a variation in applying the active gas such as ozone and the like for processing the deposited metallic layer, and not due to the gas flow rate for the deposition with the metal source gas. Therefore, in order to reduce a variation of the cell capacitance in the surface of the wafer, a control for reduce a variation in applying the active gas in the surface of the wafer is required.

### SUMMARY

According to one aspect of the present invention, there is provided an atomic layer deposition apparatus, including: a substrate pedestal on which a substrate to be processed is disposed; a first gas feeding tube, disposed in a side of the substrate pedestal to extend over the entire surface of the substrate to be processed disposed on the substrate pedestal, and capable of being supplied with a source gas from one end to the other end; and a second gas feeding tube, disposed in a side of the substrate pedestal to extend over the entire surface of the substrate to be processed disposed on the substrate pedestal, and capable of being supplied with an active gas from one end to the other end, the active gas being active with a layer of a deposited material of the source gas over the substrate to be processed, wherein the second gas feeding tube is provided with a plurality of gas blow openings for blowing the active gas that is active with the substrate to be processed, and wherein the plurality of gas blow openings are distributed at inter-opening distances that are gradually reduced as being further from the one end toward the the other end of the second gas feeding tube.

Such configuration provides improved uniformity of the blowing rates of the active gas over the entire surface of the wafer, allowing improved uniformity in the processing with the active gas over the surface of the wafer. This inhibits partial deterioration of the cell capacitance as shown in FIG. 13.

Here, any arbitrary combination of each of these constitutions or conversions between the categories of the invention such as a process, a device and the like may also be construed as being fallen within the scope of the present invention.

According to the the present invention, a partial deterioration over a wafer of the characteristics of a film deposited on the wafer through an atomic layer deposition can be prevented.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a vertical cross-sectional view, schematically illustrating an example of a configuration of an atomic layer deposition apparatus in an embodiment according to the present invention;

FIG. 2 is a plan view, schematically illustrating the example of a configuration of the atomic layer deposition apparatus in the embodiment according to the present invention;

FIG. 3 is a vertical cross-sectional view, illustrating a procedure for depositing films on a wafer in the atomic layer deposition apparatus in the embodiment of the present invention;

FIG. 4 is a vertical cross-sectional view, illustrating a procedure for depositing films on a wafer in the atomic layer deposition apparatus in the embodiment of the present invention;

FIG. 5 is a plan view, illustrating an example of an arrangement of gas blow openings;

FIGS. 6A and 6B are diagrams, which schematically illustrate the arrangement of the gas blow openings;

FIG. 7A shows a formula, and FIG. 7B is a table, showing an example of section lengths in the gas blow openings;

FIG. 8 is a diagram, illustrating an example of section lengths in the gas blow openings;

FIG. 9 is a plan view, illustrating another example of an arrangement of gas blow openings;

FIG. 10 is a diagram, schematically illustrating an exemplary implementation of other configuration of an atomic layer deposition apparatus in an embodiment of the present invention;

FIG. 11 is a diagram, schematically illustrating an exemplary implementation of other configuration of an atomic layer deposition apparatus in an embodiment of the present invention;

FIG. 12 is a diagram, illustrating a distribution of a cell capacitance in the surface; and

FIG. 13 is a diagram, illustrating a distribution of a cell capacitance in the surface.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposed.

Exemplary implementations according to the present invention will be described in detail as follows in reference to the annexed figures. In all figures, an identical numeral is assigned to an element commonly appeared in the figures, and the detailed description thereof will not be repeated.

In the following embodiments, an atomic layer deposition apparatus supplies gases containing source materials over a substrate to deposit films via an atomic layer deposition process (ALD process), which involves depositing films by adsorbing by a unit of one atomic layer. The atomic layer deposition apparatus is capable of suitably conducting, for example; an operation for supplying a metal source gas over a substrate in a process chamber to adsorb a metal source material on the substrate, thereby forming a deposition layer; and an operation for supplying an active gas over the substrate in the process chamber to activate the deposited layer, formed by adsorbing the metal source material, with the active gas. Here, the adsorption may be a chemical absorption. Alternatively, the atomic layer deposition apparatus may be capable of depositing films via a plasma enhanced atomic layer deposition process by supplying at least a type of a plasma-excited gas over the substrate.

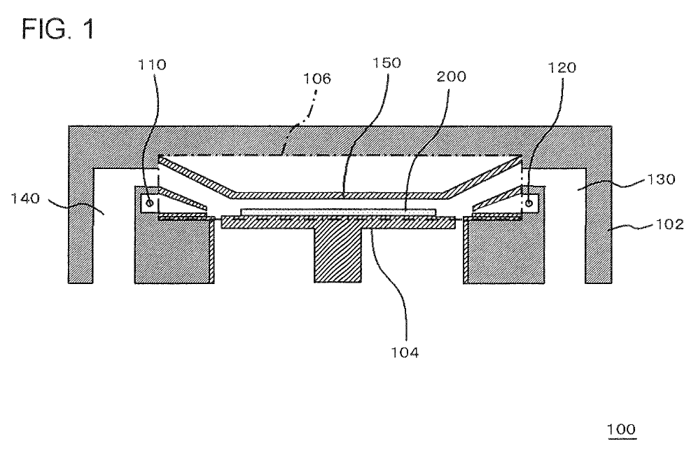

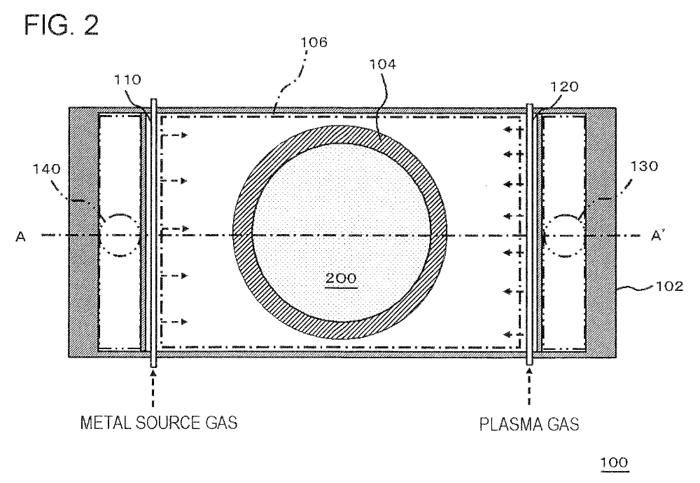

FIG. 1 and FIG. 2 are diagrams, which schematically illustrate a configuration of an atomic layer deposition apparatus in the present embodiment. FIG. 1 is a front sectional view of an atomic layer deposition apparatus 100, and FIG. 2 is a plan sectional view of the atomic layer deposition apparatus 100. FIG. 1 shows the cross section along line A-A′ of FIG. 2.

In the present embodiment, the atomic layer deposition apparatus 100 includes an external housing 102, a process chamber 106, a wafer pedestal (substrate pedestal) 104 on which a wafer 200 serving as a substrate to be processed, is disposed, a metal source gas supply tube 110 (first gas supply tube), an active gas supply tube 120 (second gas supply tube), an exhaust port 130, an exhaust port 140, and a quartz member 150. In FIG. 2, the wafer pedestal 104 is additionally shown for a convenience in the description. Each of the metal source gas supply tube 110 and the active gas supply tube 120 is disposed extending over the entire surface of the wafer 200 disposed on the wafer pedestal 104. Here, a counter-flow system, in which the metal source gas supply tube 110 and the active gas supply tube 120 are arranged to face across the wafer pedestal 104, may be employed. The quartz member 150 is provided to more effectively direct the gases in the process chamber 106 toward the wafer 200, and is also provided to prevent an adhesion of reaction products onto the inner wall of the process chamber 106. Alternatively, the wafer pedestal 104 may be configured to hold the wafer 200 without rotating the wafer.

Here, a plurality of gas blow openings for blowing the gases are provided in the metal source gas supply tube 110 and the active gas supply tube 120, respectively. Gases are supplied to the metal source gas supply tube 110 and the active gas supply tube 120, respectively, from a lower end shown in FIG. 2. The gases respectively supplied to the metal source gas supply tube 110 and the active gas supply tube 120 are blown from a plurality of gas blow openings. While the detailed arrangement of the gas blow openings will be discussed later, the active gas supply tube 120 are leastwise distributed at gradually decreased inter-tube distances from one end in the side of the upstream where the active gas is supplied toward the other end in the side of down the stream in the present embodiment. Valves, which are not shown here, are provided in the other ends in the side of the down streams of the metal source gas supply tube 110 and the active gas supply tube 120, respectively, and such valves are closed when the metal source gas and the active gas are supplied.

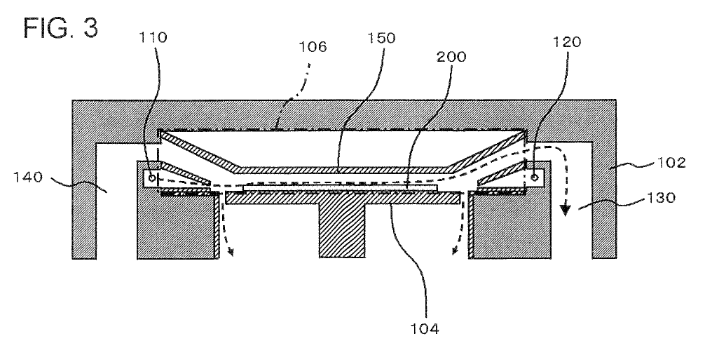

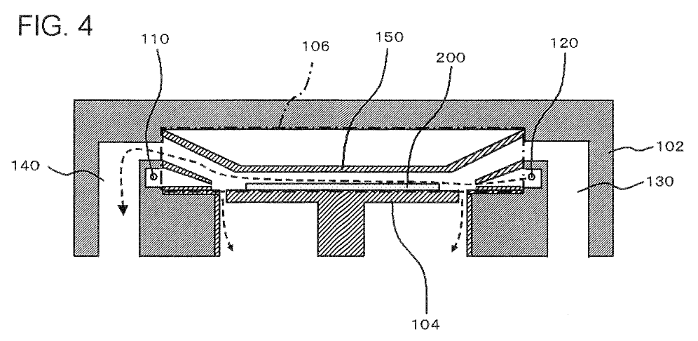

Next, the procedure for depositing films on the wafer 200 through the atomic layer deposition apparatus 100 in the present embodiment will be described in reference to FIG. 3 and FIG. 4.

The depositions of the films on the wafer 200 are conducted in the atomic layer deposition apparatus 100 by repeating the following four process steps. In the first step, as shown in FIG. 3, a metal source gas is supplied from the metal source gas supply tube 110, and is exhausted from the exhaust port 130, which is located in the opposite side facing the metal source gas supply tube 110 across the wafer 200. In the second step, an inert gas is supplied as a purge gas from the metal source gas supply tube 110 to carry out a purge, in order to remove the metal source gas supplied in the first step.

In the third step, as shown in FIG. 4, an active gas is supplied from the active gas supply tube 120 that is separated from the metal source gas supply tube 110, and is exhausted from the exhaust port 140, which is located in the opposite side facing the active gas supply tube 120 across the wafer 200. In the fourth step, an inert gas is supplied as a purge gas from the active gas supply tube 120 to carry out a purge, in order to remove the active gas supplied in the third step.

In the present embodiment, the active gas may be selected from a group consisting of oxidized gas such as nitrogen monoxide (NO), nitrogen dioxide (NO₂), nitrous oxide (N₂O), oxygen gas (O₂), ozone (O₃) and the like, nitrided gas such as nitrogen gas (N₂), ammonia (NH₃) and the like, a gaseous mixture thereof, or a gaseous mixture thereof with argon (Ar) or helium (He).

Besides, the active gas may be a plasma-activated gas which is obtained by a plasma excitation of a gas selected from a group consisting of nitrogen gas (N₂), ammonia (NH₃) oxygen gas (O₂), hydrogen gas (H₂), a gaseous mixture thereof, or a gaseous mixture thereof with argon (Ar) or helium (He). When the plasma-activated gas is employed as an active gas, remote plasma, for example, may be utilized for the plasma excitation. Although it is not shown here, a remote plasma generation chamber including a gas inlet, a waveguide, and a microwave-applying unit, for example, may be provided in a location that is different from the location of the process chamber 106, and the plasma generated in the remote plasma generation chamber may be introduced to the active gas supply tube 120 via a tube such as a silica tube and the like.

In the present embodiment, the metal source gas may be, for example, a metallic material such as an inorganic metal compound such as metal halide and the like or an organometallic material and the like. The metal source gas may be selected from various types of materials employed in the ordinary ALD process. When the metal source gas is from solid or liquid material, the material is vaporized by employing a vaporizer or a bubbling device, which is not shown here, and then the vaporized material is supplied to the process chamber 106 with a carrier gas composed of an inert gas such as argon (Ar) and the like through the metal source gas supply tube 110.

For example, when a metallic compound film containing a metallic element of hafnium (Hf) or zirconium (Zr) is deposited, M(NRR′)₄ may be employed as the metal source gas (where M contains at least one of Hf or Zr, and R and R′, which are different from each other, are hydrocarbon group). Here, alkyl group of 1C to 6C is preferable for R and R′, and more specifically, and typically methyl group, ethyl group, propyl group, tertiary butyl group and the like may be employed.

For example, when a metallic compound is employed for a capacitor element or a capacitive film of a decoupling capacitor, Zr(N(C₂H₅)₂)₄, Zr(N(CH₃)₂)₄, Zr(N(CH₃)(C₂H₅))₄ and the like may be employed for the metal source gas. A selection of such compound provides a film having a smooth surface and a prevention of a contamination of the film with particles. As a result, a capacitive film having an improved film quality with smaller leakage current can be obtained. Besides, when a metallic compound film is employed for a gate insulating film of transistor for example, Hf(N(C₂H₅)₂)₄, Hf(N(CH₃)₂)₄, Hf(N(CH₃)(C₂H₅))₄ and the like may be employed for the metal source gas. A selection of such compound provides more effective inhibition of a phenomenon of a penetration of impurity.

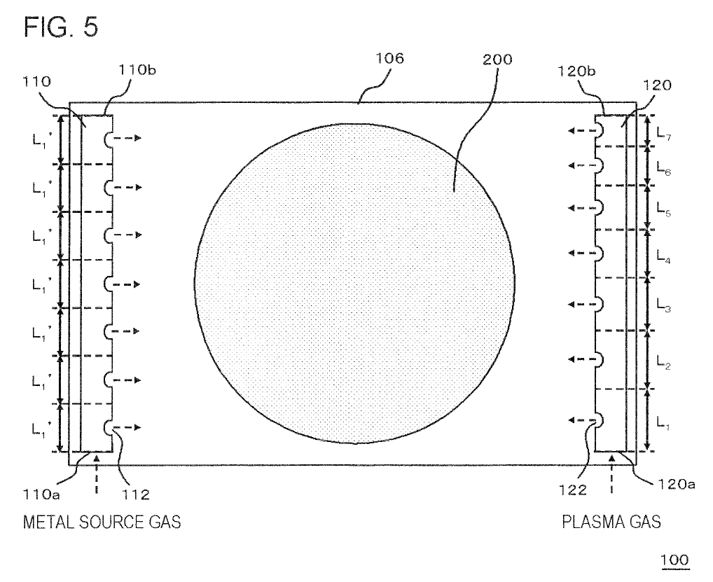

Next, the detailed arrangement of the gas blow openings will be described. FIG. 5 is a plan view, illustrating an arrangement of the gas blow openings provided in the metal source gas supply tube 110 and the active gas supply tube 120 in the present embodiment.

In active gas supply tube 120, an active gas is introduced from a first end 120a. A plurality of gas blow openings 122 are provided in the active gas supply tube 120. In the present embodiment, a plurality of gas blow openings 122 in the active gas supply tube 120 are aligned at gradually decreased inter-opening distances as being further from the first end 120a toward a second end 120b. This achieves an improved uniformity in the gas-blowing rates from the gas blow openings 122 in the upstream side and the downstream side.

On the other hand, the metal source gas is also introduced from a first end 110a in the metal source gas supply tube 110. The metal source gas may contain a carrier gas composed of an inert gas such as Ar and the like. A plurality of gas blow openings 112 are provided in the metal source gas supply tube 110. Here, the gas blow openings 112 of the metal source gas supply tube 110 may be evenly aligned from the first end 110a to a second end 110b.

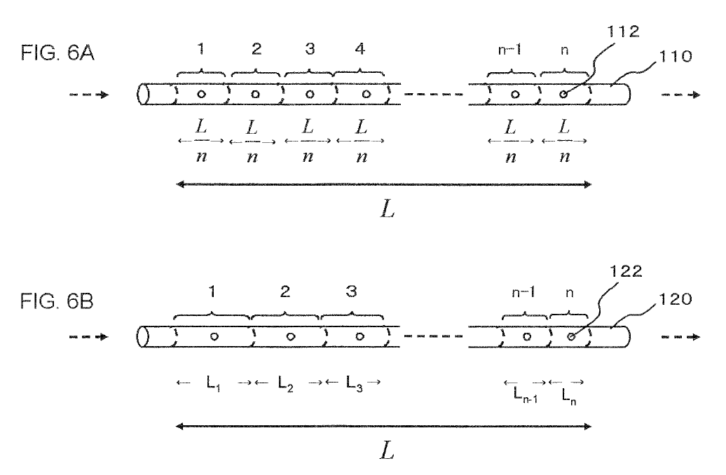

FIG. 6A is a diagram, which schematically illustrates a condition in which the gas blow openings are evenly aligned. In this embodiment, an arrangement of the gas blow openings 112 in the metal source gas supply tube 110 will be exemplified as follows. When “n” gas blow openings 112 are provided in the metal source gas supply tube 110 having a length of “L”, a section length (equivalent to inter-opening distance) for the gas blow openings 112 is L/n. In the example shown in FIG. 5, all the section lengths for the respective gas blow openings 112 in the metal source gas supply tube 110 are equally L₁′.

FIG. 6B is a diagram, which schematically illustrates a condition where the section lengths for the gas blow openings 122 in the active gas supply tube 120 are gradually decreased at an equal gradient. In such case, “n” gas blow openings 122 are also provided in the active gas supply tube 120 having a length of “L”. In addition to above, the “length L” of the active gas supply tube 120 is a length of a portion, which is provided in the lateral side of the wafer 200 and serves as a member that the gas blow openings 122 may be installed for applying the active gas over the wafer 200. The length of the metal source gas supply tube 110 is also similarly defined. Each of the section lengths of the respective gas blow openings partially constitutes the above-described “length L” and is allocated by each of the openings, and the respective gas blow openings are disposed in the central section of the respective sections.

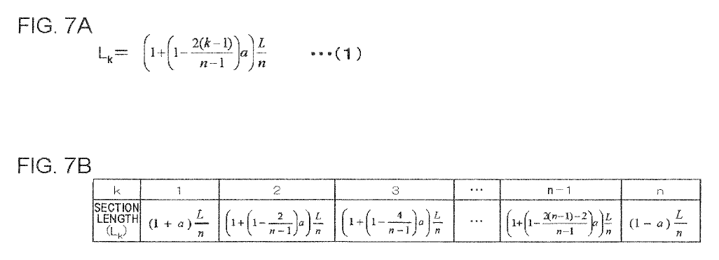

FIG. 7A presents an example of general formula for the section lengths Lₖ of the respective gas blow openings 122, which are gradually decreased at an equal gradient, when “n” gas blow openings 122 are provided in the active gas supply tube 120 of the length L. Here, “k” is a number, which is assigned for each of the gas blow openings 122 in the active gas supply tube 120, allocated sequentially from the side of the first end 120a. “k” ranges from 1 to n. In formula (1), “a” represents a rate of deviation in the section length of the gas blow opening 122 at the most end section as compared with the section length L/n that is equally allocated for all the aligned gas blow openings 122 over the length, when “n” gas blow openings 122 are provided in the active gas supply -tube 120 having a length of “L”. The rate of deviation “a” may be within a range of 0<a<1. The rate of deviation “a” may preferably be, for example, equal to or higher than 0.1 and equal to or lower than 0.8. The rate of deviation within such range would provide optimized gas-blowing levels from the respective gas blow openings 122, thereby achieving uniform characteristics of the film over the wafer surface. The section length Lₖ for the gas blow opening 122 assigned with the number “k” is presented as shown in FIG. 7B.

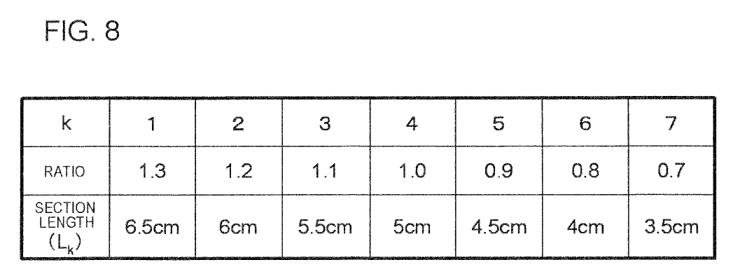

FIG. 8 is a table, showing the section lengths Lₖ of the respective gas blow openings 122 and the ratios of the section lengths, under the conditions that the length L of active gas supply tube 120=35 cm, including 7 gas blow openings 122, and the rate of deviation a=0.3. When the section length L/n=35/7=5 for the equally aligned gas blow openings 122 is taken as the reference value (1.0) here, the ratio of the section lengths of the gas blow opening 122 at the most end section in the side of the first end 120a is 1.3, and the ratio of the section length of the gas blow opening 122 at the most end section in the side of the second end 120b is 0.7.

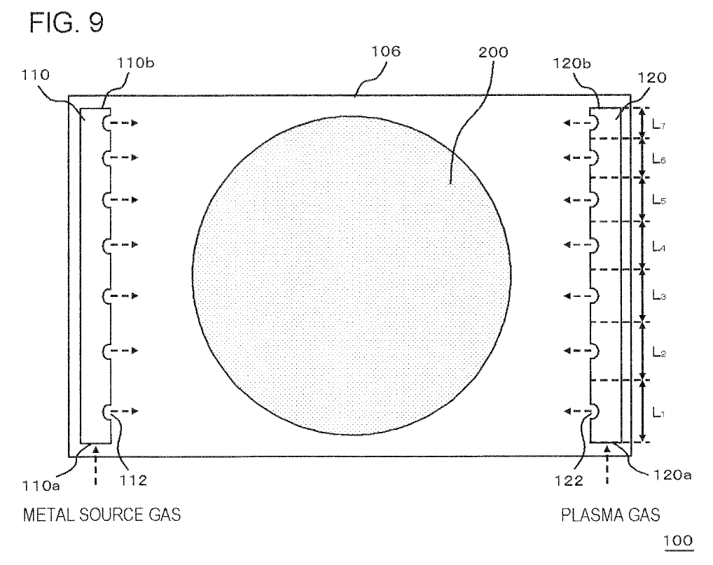

While the gas blow openings 112 are evenly distributed in the metal source gas supply tube 110 in the example illustrated in FIG. 5, the gas blow openings 112 in the metal source gas supply tube 110 may also be configured to be aligned at the larger inter-opening distance in the side of the first end 110a in the upstream where the metal source gas is supplied, and at gradually decreased inter-opening distances as further from the first end toward the downstream in the side of the second end 110b, similarly as in the case of the gas blow openings 122 in the active gas supply tube 120. Such configuration is shown in FIG. 9. For example, when the supply level of the metal source gas is extremely low, such configuration provides the improvement. In addition to above, the arrangement of the gas blow openings 112 in the metal source gas supply tube 110 may be similar as the arrangement of the gas blow openings 122 in the active gas supply tube 120, or may be otherwise different.

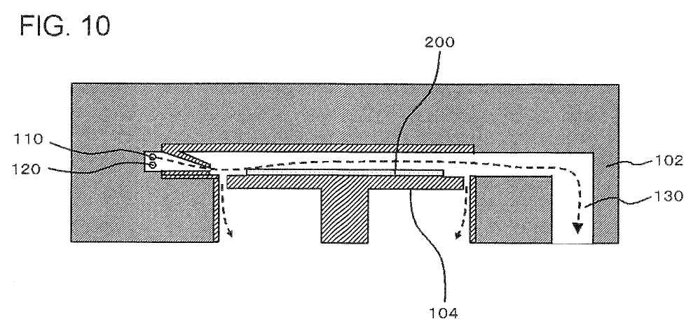

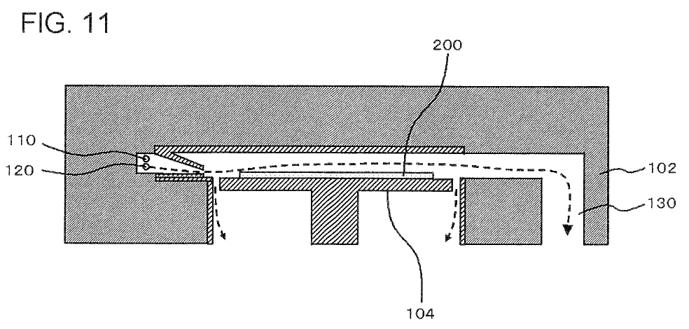

Alternatively, the atomic layer deposition apparatus 100 may be configured that the metal source gas supply tube 110 is provided in the same side as the active gas supply tube 120. Such configuration is shown in FIG. 10 and FIG. 11.

Even in such case, the same arrangement as described in reference to FIG. 5 may also be employed for the gas blow openings 122 in the active gas supply tube 120. The arrangement of the gas blow openings 112 in the metal source gas supply tube 110 may be as shown in FIG. 5, or may be as shown in FIG. 9.

In such configuration, the first step involves supplying the metal source gas from the metal source gas supply tube 110 as shown in FIG. 10, and exhausting the gas from the exhaust port 130, which is located in the opposite side facing the metal source gas supply tube 110 across the wafer 200. In the second step, an inert gas serving as a purge gas is supplied from the metal source gas supply tube 110 to achieve a purge, in order to remove the metal source gas supplied in the first step. The step for the purge may include opening a valve provided in the side of the second end 110b in the metal source gas supply tube 110 in the downstream.

The third step involves supplying the active gas from the active gas supply tube 120 and exhausting the gas from the exhaust port 130, which is located in the opposite side facing the active gas supply tube 120 across the wafer 200, as shown in FIG. 11. In the fourth step, an inert gas serving as a purge gas is supplied from the active gas supply tube 120 to achieve a purge, in order to remove the metal source gas supplied in the third step. The step for the purge may include opening a valve provided in the side of the second end 120b in the active gas supply tube 120 in the downstream.

Next, advantageous effects obtainable by employing the configuration of the atomic layer deposition apparatus 100 in the present embodiment will be described. The present inventors have found that it is critical to provide uniform supply rate of the active gas over the wafer surface in the atomic layer deposition process, in which a metal source gas is first supplied to deposit a metal source material on a substrate, and then activating the deposited layer of the metal source material with an active gas such as ozone and the like to create a film. The metal source gas as described above is adsorbed by substantially one atomic layer irrespective of the time duration for supplying the gas, when the gas is supplied over the wafer 200. Therefore, despite the supply rate of the metal source gas is not uniform over the wafer surface, a uniform deposition is achieved over the wafer for a supply of a certain time duration provided that the supply rate is an ordinary level. On the other hand, a uniform supply of the active gas over the entire surface of the wafer is required, since it is considered that the process with the active gas cause a variation in the characteristics of the film according to the time for activation. The present inventors have found that the arrangement of the gas blow openings 122 in the active gas supply tube 120 is the most critical. In the present embodiment, the arrangement of the gas blow openings 122 may be configured to be optimum. This allows an optimization of the supply rate of the active gas so as to reduce a variation in the application of the active gas over the wafer surface, according to the atomic layer deposition apparatus 100 in the present embodiment. Therefore, uniform characteristics of the film in the wafer surface can be achieved.

On the other hand, it is not necessary to strictly determine the arrangement of the gas blow openings in the metal source gas supply tube 110 for supplying the metal source gas as in the case of the active gas supply tube 120. Therefore, uniform thickness distribution can be achieved over the surface of the wafer by employing the configuration of the evenly aligned gas blow openings 112 similarly as in the conventional configuration or employing a configuration similar to the optimized arrangement in the active gas supply tube 120. When the same tube as the active gas supply tube 120 is employed for the metal source gas supply tube 110, a spare gas supply tube may be commonly utilized for both tubes.

A configuration of preventing a rotation or the like of the wafer 200 within the process chamber 106 may often be employed in the atomic layer deposition apparatus 100 in order to reduce a generation of dusts. While such configuration causes a variation in the gas supply rate over the surface of the wafer, the arrangement of the gas blow openings 122 in the active gas supply tube 120 for supplying the active gas may be optimized according to the atomic layer deposition apparatus 100 in the present embodiment to provide uniform characteristics of the film over the surface of the wafer.

### EXAMPLES

A transistor was formed on the silicon substrate, and a cylinder-like capacitor was formed above the transistor so as to be coupled to the diffusion layer of the transistor. The capacitor is formed to have, for example, a lower electrode composed of titanium nitride (TiN) and having a thickness of about 5 to 50 nm, a capacitive film having a thickness of about 5 to 15 nm, and an upper electrode composed of TiN and having a thickness of about 5 to 15 nm.

The capacitive film was manufactured in the following procedure. First of all, a metal source gas of Zr(N(CH₃)(C₂H₅))₄ was supplied in the process chamber of the atomic layer deposition apparatus with a carrier gas of Ar to cause a reaction in the surface of the lower electrode, growing only one atomic layer. Next, the supply of Zr(N(CH₃)(C₂H₅))₄ was stopped, and then an inert gas within the chamber was transferred therein as a purge gas to remove unreacted excessive Zr(N(CH₃)(C₂H₅))₄.

Subsequently, ozone (O₃) was supplied as an active gas. Oxygen (O₂) gas was introduced into, for example, a plasma generation chamber provided in a location separate from the location of the process chamber 106, which is not shown here, and exposing oxygen gas to a generated plasma to generate ozone, and then the generated ozone was introduced to the active gas supply tube 120 to cause a reaction with the one atomic layer formed on the lower electrode. Here, the introduced gas was substantially a gaseous mixture of ozone and oxygen. Next, the supply of ozone was stopped, and then an inert gas is introduced as a purge gas to remove unreacted reaction gas or byproducts, and then the supply of the purge gas was stopped. This serial cycles were repeated for only a desired cycles to obtain a capacitive film of zirconium oxide (ZrO₂).

Here, the length of the metal source gas supply tube 110 of the atomic layer deposition apparatus 100 was equivalent to the length of active gas supply tube 120, and for example, the length was determined as a predetermined length selected from the range of from L=30 centimeters to 50 centimeters. In addition, number of the gas blow openings was determined as a predetermined number selected from a range of from 10 to 50 openings for each of the both gas tubes. In addition, the flow rate of the metal source gas containing the carrier gas of Ar was determined as a predetermined flow rate selected from a range of 0.1 to 2.0 standard liters per minute (slm) in both cases. The flow rate of the active gas was also determined as a predetermined flow rate selected from a range of 0.1 to 2.0 slm in both cases.

In such status, the following conditions were employed for the alignment of the gas blow openings in the metal source gas supply tube 110 and the active gas supply tube 120 to form the above-described capacitive film, and the distributions of the cell capacitance over the surface of the wafer were measured for the respective examples.

### Example 1

### (Conditions)

The arrangement of the gas blow openings 112 in the metal source gas supply tube 110: Evenly distributed.

The arrangement of the gas blow openings 122 in the active gas supply tube 120: the inter-opening distances were decreased as further from the inlet at a certain gradient, so that a=0.5 in formula (1) in FIG. 7A.

### (Distribution of the Cell Capacitance Over the Surface of the Wafer)

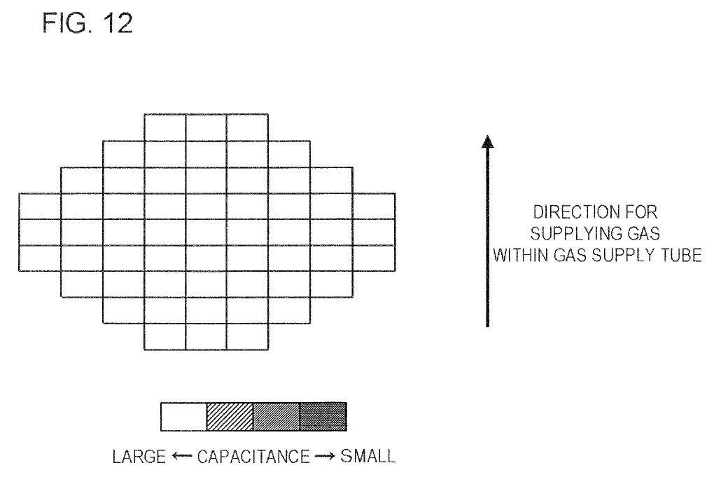

As shown in FIG. 12, the cell capacitances were equally distributed over the entire surface.

### Example 2

### (Conditions)

The arrangement of the gas blow openings 112 in the metal source gas supply tube 110: the inter-opening distances were decreased as further from the inlet at a certain gradient, so that a=0.5 in formula (1) in FIG. 7A.

The arrangement of the gas blow openings 122 in the active gas supply tube 120: the inter-opening distances were decreased as further from the inlet at a certain gradient, so that a=0.5 in formula (1) in FIG. 7A.

### (Distribution of the Cell Capacitance Over the Surface of the Wafer)

Similarly as in the case shown in FIG. 12, the cell capacitances were equally distributed over the entire surface.

### Example 3

### (Conditions)

The arrangement of the gas blow openings 112 in the metal source gas supply tube 110: Evenly distributed.

The arrangement of the gas blow openings 122 in the active gas supply tube 120: Evenly distributed.

### (Distribution of the Cell Capacitance Over the Surface of the Wafer)

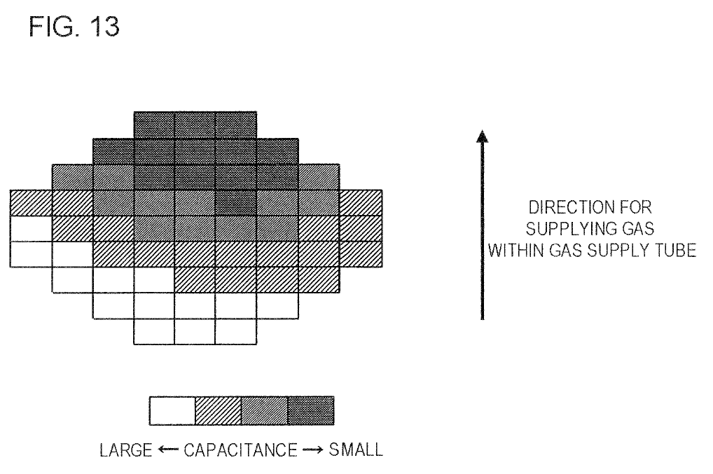

As shown in FIG. 13, uneven distribution was created in the cell capacitance.

### Example 4

### (Conditions)

The arrangement of the gas blow openings 112 in the metal source gas supply tube 110: the inter-opening distances were decreased as further from the inlet at a certain gradient, so that a=0.5 in formula (1) in FIG. 7A.

The arrangement of the gas blow openings 122 in the active gas supply tube 120: Evenly distributed.

### (Distribution of the Cell Capacitance Over the Surface of the Wafer)

Similarly as in the case shown in FIG. 13, uneven distribution is created in the cell capacitance.

When the gas blow openings 122 are evenly aligned in the upstream side and the downstream side in active gas supply tube 120, the supply of the active gas is not sufficient in the downstream side of the active gas supply tube 120 when the the metallic layer deposited on the surface of the lower electrode is activated with the active gas. Therefore, it is considered that oxidation of the metallic layer cannot sufficiently proceed and thus organic compounds contained in the metal source material are remained in the film, as illustrated in EXAMPLE 3 and EXAMPLE 4.

On the other hand, when the gas blow openings 122 are distributed in the active gas supply tube 120 with the inter-opening distances that are gradually decreased at a certain gradient as being closer to the side of the downstream as illustrated EXAMPLE 1 and EXAMPLE 2, an improved uniformity in the total gas-blowing rates over the wafer surface can be achieved, and an improved uniformity in the oxidation of the metallic layer over the wafer surface can also be achieved. This allows reducing a partial deterioration of the cell capacitance as shown in FIG. 13.

In addition, once the gas blow openings 122 are distributed in the active gas supply tube 120 with the inter-opening distances that are gradually decreased as closer to the side of the downstream as illustrated EXAMPLE 1 and EXAMPLE 2, uniform cell capacitance distribution over the entire surface can be obtained, regardless of employing the configuration of the even alignment of gas blow openings 112 in the metal source gas supply tube 110 or employing the configuration of the gas blow openings 122 in the active gas supply tube 120 with the decreased inter-opening distances. It is considered that this is caused because sufficient amount of the metal source gas is supplied over the entire surface of the wafer under the condition that the supply level of the metal source gas is within the illustrated range to achieve an adsorption of the source material by substantially single atomic layer. Therefore, the configuration of the even distribution of gas blow openings 112 in the metal source gas supply tube 110 or the configuration of the gas blow openings 122 in the active gas supply tube 120 with the decreased inter-opening distances may be employed.

As described above, the metal source gas is adsorbed by substantially one atomic layer irrespective of the time duration for supplying the gas, when the gas is supplied over the wafer 200. Thus, a uniform deposition is achieved over the wafer 200 when the time duration for supplying the metal source gas is set at a certain time duration provided that the supply rate is an ordinary level. However, the present inventor has found that under a certain condition, such as for example, when the time duration for supplying the metal source gas is set shorter than the ordinary level, the uniformity in the thickness of the capacitive film is lowered when the inter-opening distances of the gas blow openings 112 in the metal source gas supply tube 110 are decreased as further from the inlet at a certain gradient compared with the case when the inter-opening distances of the gas blow openings 112 in the metal source gas supply tube 110 are evenly distributed. Even with such the variation in the thickness of the capacitive film, as the quality of the capacitive film is improved by having the inter-opening distances of the gas blow openings 122 in the active gas supply tube 120 are decreased as further from the inlet at a certain gradient, the cell capacitances can be equally distributed over the entire surface. However, in order to achieve the strict uniformity over the entire surface for the cell, it is preferable to improve the uniformity in the thickness of the capacitive film as well.

Having such the situation into the consideration, the arrangement for the inter-opening distances of the gas blow openings 112 in the metal source gas supply tube 110 may be determined independently from the arrangement for the inter-opening distances of the gas blow openings 122 in the active gas supply tube 120. For example, as described in the above example 1, the arrangement of the gas blow openings 112 in the metal source gas supply tube 110 may be evenly distributed while the arrangement of the gas blow openings 122 in the active gas supply tube 120 is set as the inter-opening distances were decreased as further from the inlet at a certain gradient

While embodiments of the present invention has been fully described above in reference to the annexed figures, it is intended to present these embodiments for the purpose of illustrations of the present invention only, and various modifications other than that described above are also available.

While the exemplary implementations have been illustrated in the above-described embodiments, as described in reference to FIG. 5 to FIG. 8, in which a plurality of gas blow openings 122 are distributed in the active gas supply tube 120 with the continuously decreased section lengths at a constant decreasing rate, the section lengths of the gas blow openings 122 in the active gas supply tube 120 may alternatively be distributed at variable decreasing rates, provided that the decreasing rates are monotonically varied. More specifically, while the exemplary implementation of the section lengths of the gas blow openings 122, which are arithmetically changed, has been illustrated in FIGS. 7 and 8, the changes are not required to be necessarily arithmetical, and the section length Lₖ of any of the gas blow openings 122 may satisfy the relation Lₖ>Lₖ₊₁. More specifically, the gas blow openings 122 may be aligned at gradually decreased inter-opening distances as further from the upstream of the active gas supply tube 120 toward the downstream. The arrangement of the openings may be suitably designed on the basis of results of empirical depositions employing the atomic layer deposition apparatus 100 or simulations.

It is apparent that the present invention is not limited to the above embodiment, and may be modified and changed without departing from the scope and spirit of the invention.

What is claimed is:

1. An atomic layer deposition apparatus, comprising:
a substrate pedestal on which a substrate to be processed is disposed;
a first gas feeding tube, disposed in a side of said substrate pedestal to extend over the entire surface of said substrate to be processed disposed on said substrate pedestal, and capable of being supplied with a source gas from one end to the other end; and
a second gas feeding tube, disposed in a side of said substrate pedestal to extend over the entire surface of said substrate to be processed disposed on said substrate pedestal, and capable of being supplied with an active gas from one end to the other end, said active gas being active with a layer of a deposited material of said source gas over said substrate to be processed,
wherein said second gas feeding tube is provided with a plurality of gas blow openings for blowing said active gas that is active with said substrate to be processed, and
wherein said plurality of gas blow openings are distributed at inter-opening distances that are gradually reduced as being further from said one end toward said the other end of said second gas feeding tube.

2. The atomic layer deposition apparatus as set forth in claim 1, wherein said active gas is selected from a group consisting of nitrogen (N₂), ammonia (NH₃), nitrogen monoxide (NO), nitrogen dioxide (NO₂), nitrous oxide (N₂O) oxygen (O₂), ozone (O₃), a gaseous mixture thereof, or a gaseous mixture thereof with argon (Ar) or helium (He).

3. The atomic layer deposition apparatus as set forth in claim 1, wherein said active gas is a plasma-activated gas which is obtained by a plasma excitation of a gas selected from a group consisting of nitrogen (N₂), ammonia (NH₃), oxygen (O₂), hydrogen (H₂), a gaseous mixture thereof, or a gaseous mixture thereof with argon (Ar) or helium (He).

4. The atomic layer deposition apparatus as set forth in claim 1, wherein said first gas feeding tube is provided with a plurality of gas blow openings for blowing said source gas over said substrate to be processed, and wherein said plurality of gas blow openings are distributed from said one end to said another end of said first gas feeding tube at a constant inter-opening distance.

5. The atomic layer deposition apparatus as set forth in claim 1, wherein said first gas feeding tube is provided with a plurality of gas blow openings for blowing said source gas over said substrate to be processed, and wherein said plurality of gas blow openings are distributed at inter-opening distances that are gradually reduced as being further from said one end toward said another end of said first gas feeding tube

6. The atomic layer deposition apparatus as set forth in claim 1, wherein said source gas is an inorganic metal compound or an organometallic material

7. The atomic layer deposition apparatus as set forth in claim 1, wherein said source gas is firstly supplied on said substrate to deposit a source material on said substrate, and then said deposited layer of said source material is activated with said active gas.

8. The atomic layer deposition apparatus as set forth in claim 1, wherein said substrate pedestal is configured to hold said substrate without rotating said substrate.
